(19) United States
(12) Patent Application Publication
(10) Pub. No.: US 2024/0321930 A1
(43) Pub. Date: Sep. 26, 2024

(54) IMAGE SENSOR

(71) Applicant: Samsung Electronics Co., Ltd., Suwon-si (KR)

(72) Inventors: Jeongsoon Kang, Suwon-si (KR); Gyunha Park, Suwon-si (KR); Daehoon Kim, Suwon-si (KR); Jongeun Park, Suwon-si (KR); Gwideokryan Lee, Suwon-si (KR); Dongseok Cho, Suwon-si (KR)

(21) Appl. No.: 18/612,450

(22) Filed: Mar. 21, 2024

(30) Foreign Application Priority Data
Mar. 24, 2023 (KR) 10-2023-0039014
Jun. 13, 2023 (KR) 10-2023-0075546

(51) Int. Cl. H01L 27/146

(52) U.S. Cl. CPC H01L 27/14636; H01L 27/14618; H01L 27/14621; H01L 27/14627

(57) ABSTRACT

Provided is an image sensor including a first substrate including a first surface to which light is incident and a second surface opposite the first surface, a second substrate facing the second surface of the first substrate, a wiring layer between the first substrate and the second substrate and including an insulating layer and a conductive structure in the insulating layer, a first floating diffusion region provided in the first substrate, a first through electrode penetrating through the second substrate and electrically connected to the first floating diffusion region through the conductive structure, a second floating diffusion region provided in the second substrate, and a landing pad arranged on a bottom surface of the second substrate and electrically connected to the second floating diffusion region, wherein a bottom surface of the first through electrode may be in contact with the landing pad.

### CROSS-REFERENCE TO RELATED APPLICATION

This application is based on and claims priority under 35 U.S.C. § 119 to Korean Patent Application Nos. 10-2023-0039014, filed on Mar. 24, 2023, and 10-2023-0075546, filed on Jun. 13, 2023, in the Korean Intellectual Property Office, the disclosures of which are incorporated by reference herein in their entireties.

### BACKGROUND

The inventive concept relates to an image sensor, and more particularly, to a through electrode of the image sensor.

An image sensor is an element that converts an optical image into an electrical signal. Image sensors may be classified into a charge coupled device (CCD) type and a complementary metal oxide semiconductor (CMOS) type. The CMOS type image sensor is referred to as a CMOS image sensor (CIS). The CIS includes a plurality of pixels arranged two-dimensionally. Each of the pixels includes a photodiode (PD). The PD converts incident light into an electrical signal.

### SUMMARY

The inventive concept provides an image sensor configured to improve image quality.

The tasks of the inventive concept are not limited to the above-mentioned tasks, and other tasks not mentioned may be clearly understood by those of ordinary skill in the art from the following description.

According to an aspect of the inventive concept, there is provided an image sensor including a first substrate including a first surface to which light is incident and a second surface opposite the first surface, a second substrate facing the second surface of the first substrate, a wiring layer between the first substrate and the second substrate and including an insulating layer and a conductive structure in the insulating layer, a first floating diffusion region provided in the first substrate, a first through electrode penetrating through the second substrate and electrically connected to the first floating diffusion region through the conductive structure, a second floating diffusion region provided in the second substrate, and a landing pad arranged at a bottom surface of the second substrate and electrically connected to the second floating diffusion region, wherein a bottom surface of the first through electrode may be in contact with the landing pad.

According to another aspect of the inventive concept, there is provided an image sensor including a first sub-chip having an upper surface and a lower surface, and a second sub-chip below the first sub-chip, wherein the first sub-chip includes a first substrate, a first floating diffusion region arranged in the first substrate, and a first wiring layer arranged below the first substrate, and the second sub-chip includes a second substrate, a second floating diffusion region arranged in the second substrate, a second wiring layer on a bottom surface of the second substrate, a first through electrode penetrating the second substrate, a landing pad arranged in the second wiring layer and electrically connected to the first through electrode and the second floating diffusion region, and a double conversion gain gate arranged on the bottom surface of the second substrate and spaced apart from the landing pad with the second floating diffusion region therebetween, wherein a vertical level of a bottom surface of the first through electrode may be higher than a vertical level of a bottom surface of the double conversion gain gate.

According to as aspect of the inventive concept, there is provided an image sensor including a first sub-chip, a second sub-chip below the first sub-chip, and a third sub-chip below the second sub-chip, wherein the first sub-chip includes a first substrate including an upper surface to which light is incident and a lower surface opposing the upper surface, color filters arranged on the upper surface of the first substrate, a microlens layer arranged on the color filters, a first floating diffusion region within the first substrate, and a gate pattern arranged on the lower surface of the first substrate, the second sub-chip includes a second substrate, a second floating diffusion region arranged in the second substrate, a first wiring layer on a bottom surface of the second substrate, a through electrode penetrating through the second substrate and extending in a direction perpendicular to a top surface of the second substrate and electrically connected to the first floating diffusion region, and a landing pad arranged in the first wiring layer and electrically connected to the through electrode and the second floating diffusion region, and the third sub-chip includes a third substrate, a second wiring layer arranged on the third substrate and in contact with the first wiring layer, and integrated circuits arranged at a top surface of the third substrate, wherein the first wiring layer may include an insulating layer and a conductive structure in the insulating layer, and the through electrode may be spaced apart from the insulating layer.

### BRIEF DESCRIPTION OF THE DRAWINGS

Embodiments of the inventive concept will be more clearly understood from the following detailed description taken in conjunction with the accompanying drawings in which:

FIG. 1 is a block diagram of an image sensor according to an embodiment;

FIG. 2A is a circuit diagram of a pixel of an image sensor according to an embodiment;

FIG. 2B is a circuit diagram of a pixel of an image sensor according to an embodiment;

FIG. 3 is a plan view of an image sensor according to an embodiment;

FIG. 4 is a cross-sectional view taken along the line I-I′ of FIG. 3;

FIG. 5 is an enlarged view of a Q region of FIG. 4 as a cross-sectional view illustrating an image sensor according to an embodiment;

FIG. 6 is an enlarged view of a Q region of FIG. 4 as a cross-sectional view illustrating an image sensor according to an embodiment;

FIG. 7 is a cross-sectional view for describing an image sensor according to another embodiment, which corresponds to a cross section taken along line I-I′ of FIG. 3; and

FIGS. 8 to 12 are cross-sectional views sequentially illustrating a method of manufacturing an image sensor according to an embodiment.

### DETAILED DESCRIPTION OF THE EMBODIMENTS

In the present specification, the same reference numerals may refer to the same components throughout the whole specification. Hereinafter, an image sensor according to embodiments will be described with reference to the accompanying drawings.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

In the following description it will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, a component that “electrically connects” or “provides an electrical connection” provides an electrical path for an electronic signal to be transferred from one component to the other.

Embodiments described herein will be described referring to plan views and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures may have schematic properties, and shapes of regions shown in figures may exemplify specific shapes of regions of elements to which aspects of the invention are not limited.

Items described in the singular herein may be provided in plural, as can be seen, for example, in the drawings. Thus, the description of a single item that is provided in plural should be understood to be applicable to the remaining plurality of items unless context indicates otherwise.

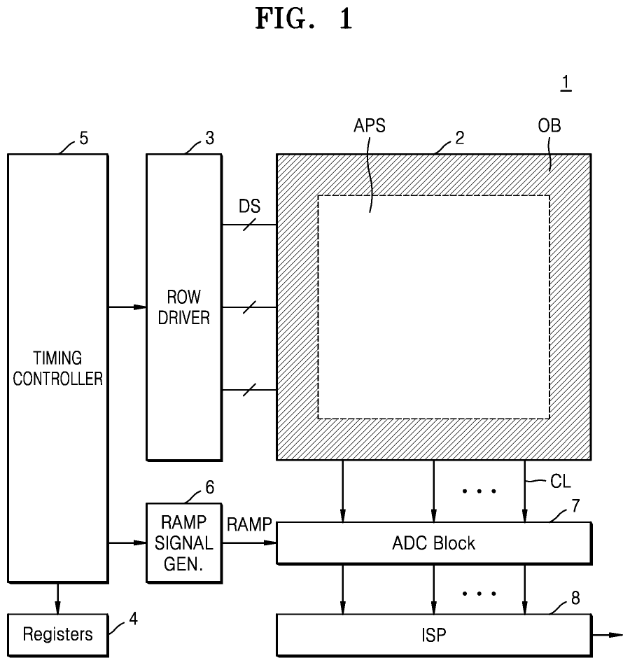

FIG. 1 is a block diagram of an image sensor according to an embodiment.

Referring to FIG. 1, an image sensor 1 may include a pixel array 2, a row driver 3, a mode setting register 4, a timing controller 5, a ramp signal generator 6, an analog-to-digital converter (ADC) block 7, and an image signal processor (ISP) 8.

The pixel array 2 includes a pixel array region (APS) and an optical black region (OB). Each of the APS and the OB includes a plurality of unit pixels arranged two-dimensionally, and each unit pixel may convert an optical signal into an electrical signal. The unit pixels included in the pixel array 2 may output an electrical signal through a corresponding column line CL in response to a plurality of driving signals DS from the row driver 3 in units of rows. Examples of driving signals DS may include a pixel selection signal, a reset signal, and a charge transmission signal.

The row driver 3 may select and drive the pixel array 2 in row units. The row driver 3 decodes a row control signal (e.g., an address signal) received from the timing controller 5, generates the plurality of driving signals DS corresponding to the decoded row line and transmits the generated driving signals DS to the pixel array 2.

The mode setting register 4 is a register in which an Application Processor (AP) electrically connected to the image sensor 1 sets an operation mode of the image sensor 1 through an interface. The AP may change the operating condition of the image sensor 1 in units of frames through the mode setting register 4.

The timing controller 5 may collectively control the operations of the respective blocks of the image sensor 1 according to the mode setting information set in the mode setting register 4.

The ramp signal generator 6 may generate a ramp signal RAMP that increases or decreases at a predetermined slope and provide the ramp signal RAMP to the ADC block 7.

The ADC block 7 converts analog electrical signals output from the column lines CL of the pixel array 2 into digital image signals. The ADC block 7 may convert the analog signals into digital signals through a correlated double sample method. The correlated double sample method may double sample a noise level and a unit pixel's signal level transferred to a column line to determine a difference level corresponding to the difference between the noise level and the signal level. The difference level may be used by the ADC block 7 to generate a digital image signal.

The ISP 8 may receive the digital image signal and process the received digital image signal to output a final image signal. The signal processor 8 may perform signal processing operations such as noise reduction processing, gain adjustment, waveform shaping processing, interpolation processing, white balance processing, gamma processing, edge emphasis processing, binning, etc.

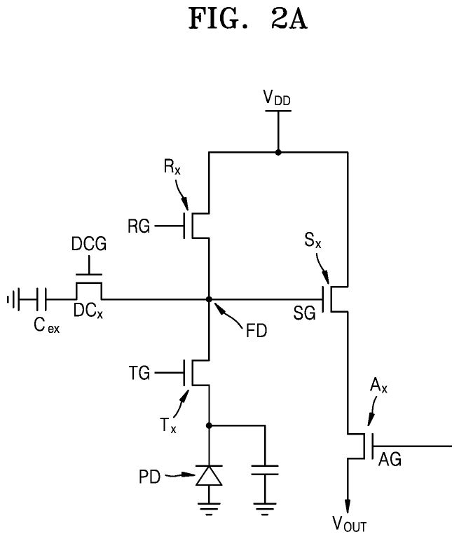

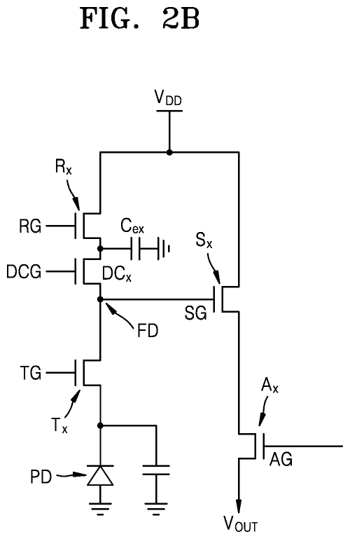

FIG. 2A is a circuit diagram of a pixel of an image sensor according to an embodiment.

Referring to FIG. 2A, each of the pixels of the image sensor may include a photoelectric conversion region PD, a transfer transistor Tx, a source follower transistor Sx, a reset transistor Rx, a selection transistor Ax, and a double conversion gain transistor DCx. The transfer transistor Tx may include a transfer gate TG. The source follower transistor Sx may include a source follower gate SG. The reset transistor Rx may include a reset gate RG. The selection transistor Ax may include a selection gate AG. The double conversion gain transistor DCx may include a double conversion gain gate DCG.

The photoelectric conversion region PD may be a photodiode including an n-type impurity region and a p-type impurity region. A floating diffusion region FD may function as a drain of the transfer transistor Tx. The floating diffusion region FD may function as a source of the reset transistor Rx. The floating diffusion region FD may be electrically connected to the source follower gate SG of the source follower transistor Sx. The source follower transistor Sx may be electrically connected to the selection transistor Ax.

The double conversion gain transistor DCx may be electrically connected to an external capacitor Cex. The floating diffusion region FD may be selectively electrically connected to the external capacitor Cex depending on the on or off state of the double conversion gain gate DCG. Accordingly, the capacitance of the floating diffusion region FD may be adjusted by the electrical connection to the external capacitor Cex. When the double conversion gain gate DCG is turned off, the capacitance of the floating diffusion region FD is reduced and the conversion gain increases, thereby improving low light quantity performance. When the double conversion gain gate DCG is turned on, the capacitance of the floating diffusion region FD increases and the full well capacity increases, thereby improving high light quantity performance. In this way, the dual conversion gain transistor DCx may perform a function of improving the image quality of the image sensor by selectively switching between an on and off state in situations of low light quantity and high light quantity.

The operation of the image sensor will be described below with reference to FIG. 2A. First, a power voltage V_{DD} is applied to the drain of the reset transistor Rx and the drain of the source follower transistor Sx while light to the image sensor is blocked. As a result, the charges remaining in the floating diffusion region FD are released by turning on the reset transistor Rx. Then, when the reset transistor Rx is turned off and light to the image sensor from the outside is not blocked and is incident to the photoelectric conversion region PD, an electron-hole pair is generated in the photoelectric conversion region PD. Holes are accumulated by moving to the p-type impurity region of the photoelectric conversion region PD, and electrons are accumulated by moving to the n-type impurity region. In this case, when the transfer transistor Tx is turned on, charges such as such electrons and holes are transmitted to the floating diffusion region FD and accumulated. The gate bias of the source follower transistor Sx changes in proportion to the accumulated amount of charges, resulting in a change in the source potential of the source follower transistor Sx. When the selection transistor Ax is turned on, a signal caused by the accumulated electric charges is read through the column line (e.g., Vout). In this case, the double conversion gain transistor DCx performs a function of adjusting the capacitance of the floating diffusion region FD.

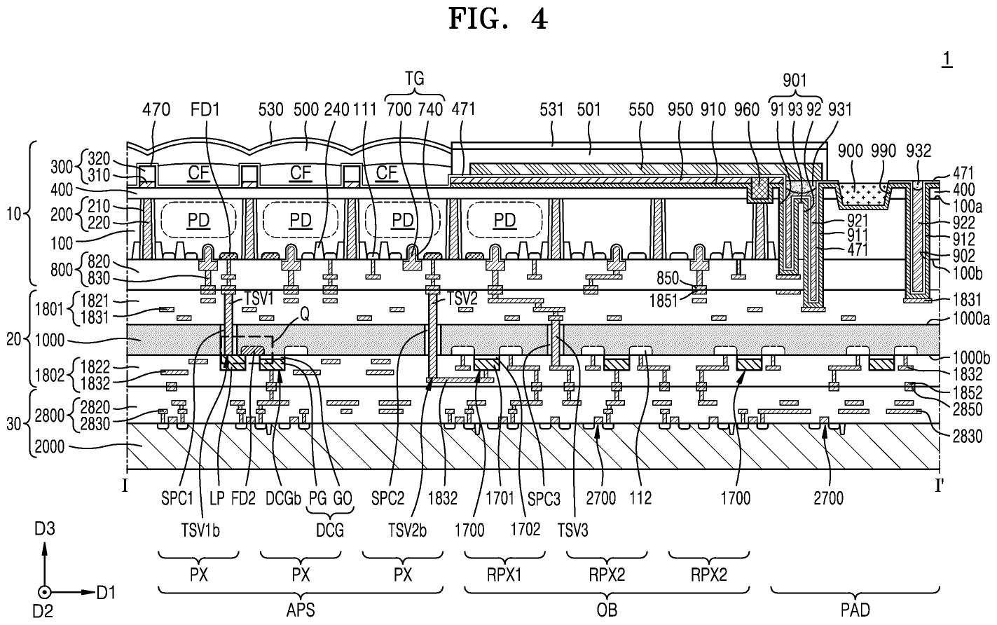

A wiring line may be electrically connected to at least one of the transfer gate TG, the source follower gate SG, the reset gate RG, the selection gate AG, and the double conversion gain gate DCG. The wiring line may be configured to apply the power voltage V_{DD} to the drain of the reset transistor Rx or the drain of the source follower transistor Sx. The wiring line may include a column line electrically connected to the selection transistor Ax. The wiring line may be the first conductive structure 830 of FIG. 4.

Although FIG. 2A illustrates a pixel including one photoelectric conversion region PD and five transistors Tx Rx, Ax, Sx, and DCx, embodiments according to the inventive concept are not limited thereto. For example, a plurality of pixels may be provided, and the reset transistor Rx, the source follower transistor Sx, or the selection transistor Ax may be shared by neighboring pixels. Accordingly, the degree of integration of the image sensor may be improved in some embodiments.

FIG. 2B is a circuit diagram of a pixel of an image sensor according to another embodiment. Hereinafter, the description of like elements as indicated by like reference characters may be limited or omitted with the understanding that the elements were previously described with reference to FIG. 2A. Elements that were not described previously or that have differences from those described may be described in greater detail with reference to FIG. 2B.

Referring to FIG. 2B, a double conversion gain transistor DCx may be placed between a floating diffusion region FD and a reset transistor Rx (e.g., in an electrical path between the elements). In addition, the external capacitor Cex may be placed between the double conversion gain transistor DCx and the reset transistor Rx (e.g., in an electrical path between the elements).

The operation of the image sensor will be described below with reference to FIG. 2B. First, the power voltage V_{DD} is applied to the drain of the reset transistor Rx and the drain of the source follower transistor Sx while light to the image sensor is blocked. As a result, the charges remaining in the floating diffusion region FD are released by turning on the reset transistor Rx and the double conversion gain transistor DCx. Then, when the reset transistor Rx is turned off and light to the image sensor from the outside is not blocked and is incident to the photoelectric conversion region PD, an electron-hole pair is generated in the photoelectric conversion region PD. Holes are accumulated by moving to the p-type impurity region of the photoelectric conversion region PD, and electrons are accumulated by moving to the n-type impurity region.

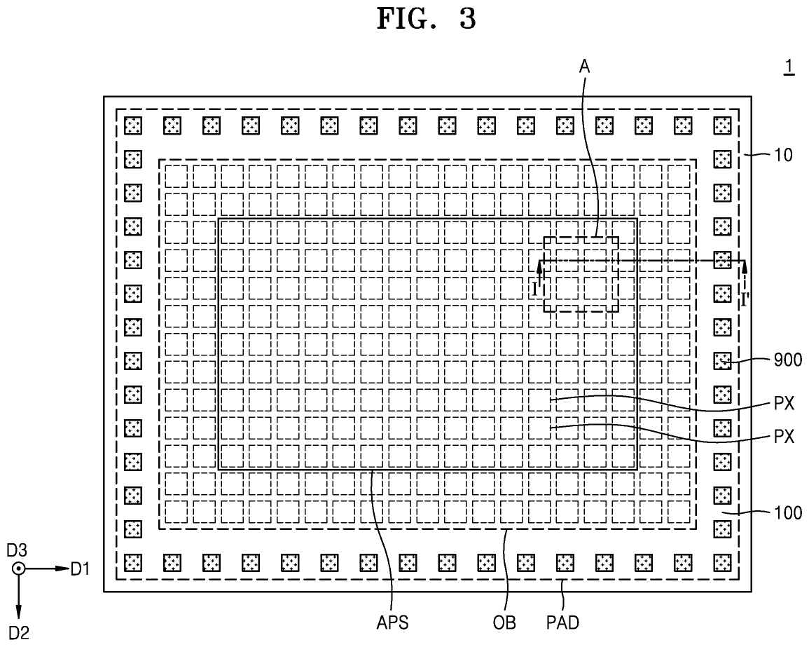

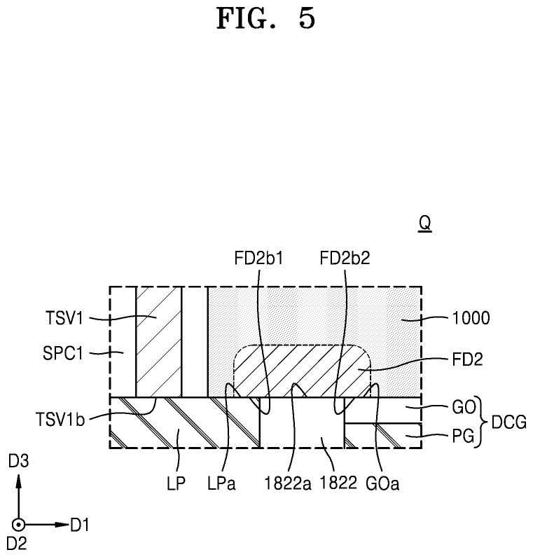

FIG. 3 is a plan view of an image sensor according to an embodiment. FIG. 4 is a cross-sectional view taken along the line I-I′ of FIG. 3. FIG. 5 is an enlarged portion Q of the cross-sectional view of FIG. 4 illustrating an image sensor according to an embodiment.

Referring to FIGS. 3 and 4, the image sensor 1 may include a first sub-chip 10, a second sub-chip 20, and a third sub-chip 30. The third sub-chip 30 may be arranged below the first sub-chip 10. The second sub-chip 20 may be placed between the first sub-chip 10 and the third sub-chip 30.

The first sub-chip 10 may be a sensor chip. The first sub-chip 10 may include a first substrate 100, a first wiring layer 800, an upper insulating layer 400, a protective layer 470, color filters CF, a fence pattern 300, and a microlens layer 500.

The first substrate 100 may include a pixel array region APS, an optical black region OB, and a pad region PAD as illustrated in FIG. 3. The pixel array region APS may be arranged at the center portion of the first substrate 100 as illustrated in FIG. 3. The pixel array region APS may include a plurality of pixel regions PX. A pixel, such as one of the pixels described with reference to FIGS. 2A and 2B, may be formed in each of the pixel regions PX of the first substrate 100. For example, components of pixels may be provided on the pixel regions PX, respectively. The pixel regions PX may output photoelectric signals representative of the magnitude of light incident on the pixel regions as described previously. The pixel regions PX may be arranged in rows and columns and may be two-dimensionally arranged as illustrated in FIG. 3. The rows may be parallel to a first direction D1. The columns may be parallel to a second direction D2. In the present specification, the first direction D1 may be parallel to a first surface 100a of the first substrate 100. The second direction D2 may be parallel to the first surface 100a of the first substrate 100 and may be different from the first direction D1. For example, the second direction D2 may be perpendicular to the first direction D1. A third direction D3 may intersect with the first direction D1 and the second direction D2. For example, the third direction D3 may be perpendicular to the first surface 100a of the first substrate 100.

As shown in the plan view of FIG. 3, the pad region PAD may be provided at an edge portion of the first substrate 100 and may surround the pixel array region APS. Pad terminals 900 may be provided on the pad region PAD. The pad terminals 900 may output electrical signals generated in the pixel regions PX. The pad terminals 900 may output electrical signals to a component external to the image sensor. Alternatively, an external electrical signal or voltage may be transmitted to the pixel regions PX through the pad terminals 900. Since the pad region PAD is arranged at the edge portion of the first substrate 100, the pad terminals 900 may be easily electrically connected to an external component. The optical black region OB may be placed between the pixel array region APS and the pad region PAD.

The first substrate 100 may have the first surface 100a and a second surface 100b opposing each other. The first surface 100a of the first substrate 100 may be a rear surface, and the second surface 100b of the first substrate 100 may be a front surface. A rear surface may be a surface facing away from a base structure such as a circuit board and a front surface may be a surface facing towards the base structure. Light may be incident on the first surface 100a of the first substrate 100. The first substrate 100 may be a semiconductor substrate or a silicon on insulator (SOI) substrate. The semiconductor substrate may be formed of and/or include, for example, a silicon substrate, a germanium substrate, or a silicon-germanium substrate. The first substrate 100 may further include a Group III element. The Group III element may be an impurity of a first conductivity type. The first substrate 100 may include impurities of the first conductivity type to have a first conductivity type. For example, the first conductivity type impurities may include p-type impurities such as aluminum (Al), boron (B), indium (In), and/or gallium (Ga).

On the pixel array region APS, the first substrate 100 may include photoelectric conversion regions PD. The photoelectric conversion regions PD may be placed between the first surface 100a and the second surface 100b of the first substrate 100. The photoelectric conversion regions PD may be provided to the pixel regions PX in the first substrate 100, respectively. Each of the photoelectric conversion regions PD may perform the same function and role as the photoelectric conversion region PD of FIGS. 2A and 2B. The photoelectric conversion regions PD may further include a Group VI element. The Group VI element may be impurities of a second conductivity type. The photoelectric conversion regions PD may be regions doped with impurities of the second conductivity type in the first substrate 100. The impurities of the second conductivity type may have a conductivity type opposite to the impurities of the first conductivity type. The second conductivity type impurities may include n-type impurities such as phosphorus, arsenic, bismuth, and/or antimony. The photoelectric conversion regions PD may be arranged to be spaced apart from the first surface 100a of the first substrate 100 but embodiments are not limited thereto.

An isolation pattern 200 is provided in the first substrate 100 and may define pixel regions PX. For example, the isolation pattern 200 may be provided between the pixel regions PX of the first substrate 100. The isolation pattern 200 may be a pixel isolation pattern. The isolation pattern 200 may be provided in a trench formed in the first substrate 100. The isolation pattern 200 may be a deep trench isolation layer. The isolation pattern 200 may penetrate through the first substrate 100. A top surface of the isolation pattern 200 may be coplanar with the first surface 100a of the first substrate 100. The bottom surface of the isolation pattern 200 may oppose the top surface of the isolation pattern 200. The isolation pattern 200 may include a first isolation pattern 210 and a second isolation pattern 220. The first isolation pattern 210 may be provided along a sidewall of the trench. The first isolation pattern 210 may be formed of and/or include, for example, a silicon-based insulating material (e.g., silicon nitride, silicon oxide, and/or silicon oxynitride) and/or a high dielectric material (e.g., hafnium oxide and/or aluminum oxide). In another example, the first isolation pattern 210 may be formed of and/or include a plurality of layers, and the plurality of layers may include different materials. The first isolation pattern 210 may have a refractive index that is lower than a refractive index of the first substrate 100. Accordingly, a crosstalk phenomenon between the pixel regions PX of the first substrate 100 may be prevented/reduced by the first isolation pattern 210.

The second isolation pattern 220 may be provided in the first isolation pattern 210. The first isolation pattern 210 may be disposed between the second isolation pattern 220 and the first substrate 100. The second isolation pattern 220 may be spaced apart from the first substrate 100 by the first isolation pattern 210. Accordingly, during an image sensor operation, the second isolation pattern 220 may be electrically isolated from the first substrate 100. The second isolation pattern 220 may be formed of and/or include a crystalline semiconductor material, for example, polycrystalline silicon. For example, the second isolation pattern 220 may further include a dopant, and the dopant may include first conductivity type impurities or second conductivity type impurities. For example, the second isolation pattern 220 may include doped polycrystalline silicon.

The color filters CF may be arranged on the pixel regions PX on the first surface 100a of the first substrate 100, respectively. For example, the color filters CF may be provided at positions corresponding to the photoelectric conversion regions PD, respectively. Each of the color filters CF may include any one of a red filter, a blue filter, and a green filter. Other colors are possible, and embodiments are not limited to these colors. The color filters CF may form color filter arrays. For example, the color filters CF may form an array horizontally arranged in the first direction D1 and the second direction D2.

The fence pattern 300 may be arranged on the isolation pattern 200. For example, the fence pattern 300 may overlap with the isolation pattern 200 in a plan view. The fence pattern 300 may be placed between two adjacent color filters CF to separate the color filters CF. For example, the plurality of color filters CF may be physically and optically isolated from each other by the fence pattern 300.

The fence pattern 300 may vertically overlap the isolation pattern 200. From a plan view, the fence pattern 300 may surround each of the pixel regions PX. For example, the fence pattern 300 may surround each of the color filters CF. The fence pattern 300 may include a first fence pattern 310 and a second fence pattern 320. The first fence pattern 310 may be arranged between the isolation pattern 200 and the second fence pattern 320.

The first fence pattern 310 may function as a barrier layer. According to embodiments, electrical charges may be trapped in an interface between the first substrate 100 and the upper insulating layer 400. A bottom surface of the first fence pattern 310 may be in contact with the upper insulating layer 400 to remove charges trapped by the first fence pattern 310. The first fence pattern 310 may function as an adhesive layer, so that the second fence pattern 320 may be attached to the upper insulating layer 400 by the first fence pattern 310.

The first fence pattern 310 may be formed of and/or include a conductive material such as a metal and/or metal nitride. For example, the first fence pattern 310 may include titanium and/or titanium nitride. The second fence pattern 320 may be arranged on the first fence pattern 310. The second fence pattern 320 may be formed of and/or include a material that is different from that of the first fence pattern 310. The second fence pattern 320 may include an organic material. The second fence pattern 320 may be formed of and/or include a low refractive material and may have insulating properties. The second fence pattern 320 may have, for example, a rectangular cross-section.

The upper insulating layer 400 may be placed between the first substrate 100 and the color filters CF and between the isolation pattern 200 and the fence pattern 300. The upper insulating layer 400 may cover the first surface 100a of the first substrate 100 and the top surface of the isolation pattern 200. The upper insulating layer 400 may be a rear insulating layer. The upper insulating layer 400 may include a bottom antireflective coating (BARC) layer. The upper insulating layer 400 may include a plurality of layers, and the layers of the upper insulating layer 400 may perform different functions.

The upper insulating layer 400 may include fixed charge layers (not shown). Each of the fixed charge layers may be formed of and/or include a metal oxide layer or a metal fluoride layer. The metal oxide layer may include oxygen in an amount less than the stoichiometric composition ratio, and the metal fluoride layer may include fluorine in an amount less than the stoichiometric composition ratio. For example, the metal oxide layer and the metal fluoride layer may be made of metal oxide or metal fluoride containing at least one metal selected from the group consisting of hafnium (Hf), zirconium (Zr), aluminum (Al), tantalum (Ta), titanium (Ti), yttrium, and lanthanide. As a result, the fixed charge layers have a negative fixed charge and may generate hole accumulation. The occurrence of a dark current (i.e., current that flows when there is no incident light) and a white spot (i.e., a pixel region PX that appears bright when light is not incident on the pixel region PX) of the first substrate 100 may be effectively reduced by the fixed charge layers.

The protective layer 470 may cover a top surface of the upper insulating layer 400, a sidewall of the fence pattern 300, and a top surface of the fence pattern 300. The thickness of the protective layer 470 may be smaller than the thickness of the upper insulating layer 400. The protective layer 470 may be formed of and/or include a high dielectric material and may have insulation properties. For example, the protective layer 470 may be formed of and/or include aluminum oxide or hafnium oxide. Specifically, the protective layer 470 may include aluminum oxide but is not limited thereto. The protective layer 470 may protect the photoelectric conversion regions PD of the first substrate 100 from an external environment such as moisture.

Color filters CF are provided on the first surface 100a of the first substrate 100 and may be arranged in a side-by-side pattern. The types of the color filters CF may vary. For example, each of the color filters CF may be one of a red filter, a blue filter, or a green filter. Color filters CF that are adjacent to each other may have the fence pattern 300 therebetween and they may be laterally spaced apart from each other by the fence pattern 300.

A microlens layer 500 may be arranged on the color filters CF and on the fence pattern 300. The microlens layer 500 is transparent and therefore is able to transmit light. External light may be incident on the first surface 100a of the first substrate 100 through the microlens layer 500 and the color filters CF. In this case, light may be incident in a direction inclined with respect to the first surface 100a of the first substrate 100. The fence pattern 300 may prevent light incident on any one color filter CF from being transmitted to the photoelectric conversion region PD of the adjacent pixel region PX. Accordingly, generation of crosstalk between the pixel regions PX of the image sensor 1 may be reduced.

The microlens layer 500 may include an organic material such as an organic polymer. For example, the microlens layer 500 may include a photoresist material or a thermosetting resin.

A lens coating layer 530 may be arranged on the microlens layer 500. The lens coating layer 530 may be transparent. The lens coating layer 530 may conformally cover the top surface of the microlens layer 500. The lens coating layer 530 may protect the microlens layer 500.

The first substrate 100 may include first floating diffusion regions FD1 and first impurity regions 111. The first floating diffusion regions FD1 and the first impurity regions 111 may be arranged in the pixel regions PX in the first substrate 100, respectively. The first floating diffusion regions FD1 and the first impurity regions 111 may be arranged adjacent to the second surface 100b of the first substrate 100. The first floating diffusion regions FD1 may perform the same function and role as those of the floating diffusion region FD of FIGS. 2A and 2B.

Top surfaces of the first floating diffusion regions FD1 and the first impurity regions 111 may be spaced apart from the photoelectric conversion regions PD. The first floating diffusion regions FD1 and the first impurity regions 111 may be regions doped with second conductivity type impurities (e.g., n-type impurities).

The first impurity regions 111 may be active regions. In this case, the active regions may refer to regions for operations of the transistor and may include source/drain regions of the transistor described with reference to FIGS. 2A and 2B. The transistor may include the transfer transistor Tx described with reference to FIGS. 2A and 2B.

A device isolation pattern 240 may be provided in the first substrate 100. The device isolation pattern 240 may define active regions. Specifically, in each pixel region PX, the device isolation pattern 240 may define first floating diffusion regions FD1 and first impurity regions 111. The first floating diffusion regions FD1 and the first impurity regions 111 may be isolated from each other by the device isolation pattern 240. For example, the device isolation pattern 240 may be arranged on one side of any one of the first floating diffusion regions FD1 or the first impurity regions 111 in the first substrate 100. The device isolation pattern 240 may be a shallow trench isolation (STI) layer. For example, the height of the device isolation pattern 240 may be less than the height of the isolation pattern 200. A portion of the device isolation pattern 240 may contact a sidewall of the first isolation pattern 210. The device isolation pattern 240 may be formed of and/or include, for example, silicon oxide, silicon nitride, and/or silicon oxynitride.

A gate pattern 700 may be arranged on the second surface 100b of the first substrate 100. The gate pattern 700 may function as a gate electrode of the transfer transistor Tx described above with reference to FIG. 1. For example, the gate pattern 700 may be a portion of the transfer gate TG. A plurality of gate patterns 700 may be provided. The plurality of gate patterns 700 may each be arranged on a respective pixel region PX.

Each of the gate patterns 700 may have a buried gate structure. For example, the gate pattern 700 may include a first portion and a second portion. The first portion of the gate pattern 700 may be arranged on the second surface 100b of the first substrate 100. The second portion of the gate pattern 700 may protrude into the first substrate 100. The second portion of the gate pattern 700 may be directly connected to the first portion. Unlike the illustration, the gate pattern 700 may have a planar gate structure. In this case, the gate pattern 700 may not include a second portion. The gate pattern 700 may be formed of and/or include a metal material, a metal silicide material, polycrystalline silicon, and a combination thereof. In this case, the polycrystalline silicon may include doped polycrystalline silicon.

A gate insulating pattern 740 may be placed between the gate pattern 700 and the first substrate 100. The gate insulating pattern 740 may be formed of and/or include, for example, a silicon-based insulating material (e.g., silicon oxide, silicon nitride, and/or silicon oxynitride) and/or a high dielectric material (e.g., hafnium oxide and/or aluminum oxide).

The first wiring layer 800 may cover the second surface 100b of the first substrate 100 on the pixel array region APS, the optical black region OB, and the pad region PAD of the first substrate 100. The first wiring layer 800 may include a first insulating layer 820 and a first conductive structure 830. The first insulating layer 820 may include a single layer or a plurality of layers. The first insulating layer 820 may cover the second surface 100b of the first substrate 100 and the gate pattern 700. The first insulating layer 820 may contain a silicon-based insulating material such as silicon oxide, silicon nitride, and/or silicon oxynitride.

The first conductive structure 830 may be provided in the first insulating layer 820. The first conductive structure 830 may include a via portion and a wiring portion. The via portion and the wiring portion may be provided in the first insulating layer 820. The via portion may be electrically connected to any one of the first floating diffusion region FD1, the first impurity regions 111, and the gate pattern 700. The wiring portion may be electrically connected to the via portion. The via portion also penetrates through at least a portion of the first insulating layer 820 and may be electrically connected to the wiring portion. The first conductive structure 830 may receive the photoelectric signals output from the photoelectric conversion regions PD.

First bonding pads 850 may be arranged adjacent to each other on a bottom surface of the first insulating layer 820. Each of the first bonding pads 850 may be electrically connected to the first conductive structure 830. Each of the first bonding pads 850 may be formed of and/or include a metal such as copper. The various pads of a device described herein may be conductive terminals providing an electrical connection to internal wiring of the device, and may transmit signals and/or supply voltages between an internal wiring and/or internal circuit of the device and an external source electrically connected to the pad. For example, the first bonding pads 850 provide conductive terminals that provide an electrical connection to the first conductive structure 830. The various pads may be provided on or near an external surface of the device, which may be internal to a package of interconnected devices, and may generally have a planar surface area (often larger than a corresponding surface area of the internal wiring to which they are connected) to promote an electrical connection to a further terminal, such as a bump or solder ball, and/or an external wiring.

The pad terminal 900 may be arranged on the pad region PAD of the first substrate 100. The pad terminal 900 may be arranged on the first surface 100a of the first substrate 100. The pad terminal 900 may be embedded in the first substrate 100. For example, a pad trench 990 may be formed in the first surface 100a of the pad region PAD of the first substrate 100, and the pad terminal 900 may be provided within the pad trench 990. The pad terminal 900 may be formed of and/or include a metal such as aluminum, copper, tungsten, titanium, tantalum, or an alloy thereof. In the process of mounting the image sensor 1, a bonding wire may be formed on the pad terminal 900 to be electrically connected to the pad terminal 900. The pad terminal 900 may be electrically connected to an external device through the bonding wire. As shown in FIG. 3, a plurality of pad terminals 900 may be provided.

A first through hole 901 may be arranged on a first side of the pad terminal 900. The first through hole 901 may include a first through hole portion 91, a second through hole portion 92, and a third through hole portion 93. The first through hole portion 91 may pass through the upper insulating layer 400, the first substrate 100, and the first wiring layer 800 and may have a first bottom surface. A first bottom surface of the first through hole 901 may expose the first conductive structure 830. The second through hole portion 92 penetrates through the upper insulating layer 400, the first substrate 100, and the first wiring layer 800 and may extend into an upper portion of a second wiring layer 1801. The second through hole portion 92 may have a second bottom surface, and the second bottom surface of the second through hole portion 92 may expose a top surface of the second conductive structure 1831. A second bottom surface of the first through hole 901 may be arranged at a lower level than the first bottom surface of the first through hole 901. A sidewall of the second through hole portion 92 may be spaced apart from the sidewall of the first through hole portion 91. The third through hole portion 93 may be provided between an upper portion of the first through hole portion 91 and an upper portion of the second through hole portion 92, and may be directly connected to an upper portion of the first through hole portion 91 and an upper portion of the second through hole portion 92. A first conductive pattern 911, a protective insulating layer 471, and a first buried pattern 921 may be provided in the first through hole 901. The first conductive pattern 911 may cover inner walls of the first through hole portion 91, the second through hole portion 92, and the third through hole portion 93. The first conductive pattern 911 may be a portion of the conductive pattern layer 910.

The first conductive pattern 911 may cover the sidewall and the first bottom surface of the first through hole 901. The first conductive pattern 911 may be in contact with a top surface of the first conductive structure 830. Accordingly, the first conductive structure 830 may be electrically connected to any one pad terminal 900 (e.g., a first pad terminal) through the first conductive pattern 911. During the operation of the image sensor 1, a voltage may be applied to the first conductive structure 830 through any one pad terminal 900 and the first conductive pattern 911. A voltage may be applied to the second isolation pattern 220 through the first conductive pattern 911 and the contact plug 960. The voltage may be a negative bias voltage.

The first conductive pattern 911 may also cover the second bottom surface of the first through hole 901. The first conductive pattern 911 may be electrically connected to a top surface of the second conductive structure 1831. First integrated circuits 1700 in the second sub-chip 20 may be electrically connected to any one pad terminal 900 (e.g., the first pad terminal) through the second conductive structure 1831 and the first conductive pattern 911. The first conductive pattern 911 may function as an electrical path between the first integrated circuits 1700 of the second sub-chip 20 and the transistor of the first sub-chip 10. The first conductive pattern 911 may be formed of and/or include a metal such as copper, tungsten, aluminum, titanium, tantalum, or an alloy thereof.

The first buried pattern 921 may be provided in the first through hole 901 to fill the first through hole 901. The first buried pattern 921 includes a low refractive material and may have insulating properties. The top surface of the first buried pattern 921 may have a recessed portion. For example, the center portion of the top surface of the first buried pattern 921 may be arranged at a lower level than the edge portion of the first buried pattern 921.

A first capping pattern 931 may be arranged on the top surface of the first buried pattern 921 to fill the recessed portion. The top surface of the first capping pattern 931 may be substantially flat. The first capping pattern 931 may include an insulating polymer such as a photoresist material.

The second through hole 902 may be arranged on a second side of the pad terminal 900. The second side of the pad terminal 900 may be different from the first side of the pad terminal 900. The second through hole 902 may penetrate through the upper insulating layer 400, the first substrate 100, and the first wiring layer 800. The second through hole 902 may penetrate through a portion of the second wiring layer 1801 to expose the second conductive structure 1831.

The second conductive pattern 912 may conformally cover the sidewall and the bottom surface of the second through hole 902. The second conductive pattern 912 may be electrically connected to the pad terminal 900. The second conductive pattern 912 may be electrically connected to the second conductive structure 1831. The second conductive pattern 912 may be a portion of the conductive pattern layer 910.

A second buried pattern 922 may be provided in the second through hole 902 to fill the second through hole 902. The second buried pattern 922 includes a low refractive material and may have insulating properties. The top surface of the second buried pattern 922 may have a recessed portion.

A second capping pattern 932 may be arranged on a top surface of the second buried pattern 922 to fill the recessed portion. The top surface of the second capping pattern 932 may be substantially flat. The second capping pattern 932 may include an insulating polymer such as a photoresist material.

The protective insulating layer 471 may be provided to extend onto the pad region PAD of the first substrate 100. The protective insulating layer 471 may be provided on the top surface of the upper insulating layer 400 and may extend into the first through hole 901 and the second through hole 902. The protective insulating layer 471 may be placed between the first conductive pattern 911 and the first buried pattern 921 in the first through hole 901. The protective insulating layer 471 may be placed between the second conductive pattern 912 and the second buried pattern 922 in the second through hole 902. The protective insulating layer 471 may expose the pad terminal 900.

An organic layer 501 and a coating layer 531 may be further provided on the pad region PAD of the first substrate 100. The organic layer 501 may cover the first capping pattern 931 and a portion of the protective insulating layer 471 on the first surface 100a of the first substrate 100. The organic layer 501 may expose a top surface of the pad terminal 900.

The optical black region OB of the first substrate 100 may be placed between the pixel array region APS and the pad region PAD. The optical black region OB may include a first reference pixel region RPX1 and a second reference pixel region RPX2. The first reference pixel region RPX1 may be arranged between the second reference pixel region RPX2 and the pixel array region APS. In the optical black region OB, the photoelectric conversion region PD may be provided in the first reference pixel region RPX1. The photoelectric conversion region PD of the first reference pixel region RPX1 may have the same planar area and volume as the photoelectric conversion regions PD of the pixel regions PX. The photoelectric conversion region PD may not be provided in the second reference pixel region RPX2. Each of the first impurity regions 111, the gate pattern 700, and the device isolation pattern 240 may be arranged in each of the first and second reference pixel regions RPX1 and RPX2. The first impurity regions 111, the gate pattern 700, and the device isolation pattern 240 are the same as described above.

The upper insulating layer 400 may extend onto the optical black region OB and the pad region PAD of the first substrate 100 and may cover the first surface 100a of the first substrate 100.

A light blocking layer 950 may be provided on the first surface 100a of the optical black region OB of the first substrate 100. The light blocking layer 950 may be arranged on the top surface of the upper insulating layer 400. Light may not be incident on the photoelectric conversion region PD of the optical black region OB due to the light blocking layer 950. Pixels of the first and second reference pixel regions RPX1 and RPX2 of the optical black region OB may output a noise signal without outputting a photoelectric signal. The noise signal may be generated by electrons generated by heat generation, dark current, or the like. Since the light blocking layer 950 does not cover the pixel array region APS, light may be incident on the photoelectric conversion regions PD in the pixel array region APS. Noise signals may be removed from the photoelectric signals output from the pixel regions PX. The light blocking layer 950 may be formed of and/or include, for example, a metal such as tungsten, copper, aluminum, or an alloy thereof.

In the optical black region OB of the first substrate 100, a conductive pattern layer 910 may be arranged between the upper insulating layer 400 and the light blocking layer 950. The conductive pattern layer 910 may serve as a barrier layer or an adhesive layer. The conductive pattern layer 910 may be formed of and/or include a metal and/or metal nitride. For example, the conductive pattern layer 910 may include titanium and/or titanium nitride. The conductive pattern layer 910 may not extend onto the pixel array region APS of the first substrate 100.

The first conductive pattern 911 and the second conductive pattern 912 may be portions of the conductive pattern layer 910. The first conductive pattern 911 may be a portion of the conductive pattern layer 910 that covers a sidewall and a bottom surface of the first through hole 901. The second conductive pattern 912 may be a portion of the conductive pattern layer 910 that covers a sidewall and a bottom surface of the second through hole 902. The conductive pattern layer 910 may extend onto the pad region PAD. The conductive pattern layer 910 may be placed between the pad terminal 900 and the upper insulating layer 400 and between the pad terminal 900 and the first substrate 100. The conductive pattern layer 910 may be electrically connected to the pad terminal 900.

In the optical black region OB of the first substrate 100, a contact plug 960 may be provided on the first surface 100a of the first substrate 100. The contact plug 960 may be arranged in the upper insulating layer 400. The contact plug 960 may be arranged on a top surface of the outermost one of the isolation patterns 200. A contact trench may be formed in the first surface 100a of the first substrate 100, and the contact plug 960 may be provided in the contact trench. The contact plug 960 may be formed of and/or include a material that is different from the light blocking layer 950. For example, the contact plug 960 may include a metallic material such as aluminum. The conductive pattern layer 910 may extend between the contact plug 960 and the upper insulating layer 400 and between the contact plug 960 and the isolation pattern 200. The contact plug 960 may be electrically connected to the second isolation pattern 220 through the conductive pattern layer 910. Accordingly, a negative bias voltage may be applied to the second isolation pattern 220 by way of the contact plug 960.

In the optical black region OB of the first substrate 100, the protective insulating layer 471 may be arranged on the top surface of the light blocking layer 950 and the top surface of the contact plug 960. The protective insulating layer 471 may be formed of and/or include the same material as the protective layer 470 and may be directly connected to the protective layer 470. The protective insulating layer 471 may be integrally formed with the protective layer 470 (e.g., formed in the same process with the same material). As another example, the protective insulating layer 471 may be formed by a separate process from the protective layer 470 and may be spaced apart from the protective layer 470. The protective insulating layer 471 may be formed of and/or include a high dielectric material (e.g., aluminum oxide and/or hafnium oxide).

A filtering layer 550 may be further arranged on the first surface 100a of the optical black region OB. The filtering layer 550 may cover a top surface of the protective insulating layer 471. The filtering layer 550 may block light having a wavelength that is different from those of the color filters CF. For example, the filtering layer 550 may block infrared rays. The filtering layer 550 may include a blue color filter but is not limited thereto.

The organic layer 501 may be arranged on the top surface of the filtering layer 550 in the optical black region OB. The organic layer 501 may be transparent. A top surface of the organic layer 501 may face away from the first substrate 100 and may be substantially flat. The organic layer 501 may be formed of and/or include, for example, an organic polymer. The organic layer 501 may have insulating properties. Unlike the illustration, the organic layer 501 may be directly connected to the microlens layer 500. The organic layer 501 may include the same material as the microlens layer 500.

The coating layer 531 may be provided on the organic layer 501. The coating layer 531 may conformally cover the top surface of the organic layer 501. The coating layer 531 includes an insulating material and may be transparent. The coating layer 531 may include the same material as the lens coating layer 530.

The second sub-chip 20 may be arranged below the first sub-chip 10. The second sub-chip 20 may include a second wiring layer 1801, a third wiring layer 1802, and a second substrate 1000. The third wiring layer 1802 may be arranged below the second wiring layer 1801. The second substrate 1000 may be placed between the second wiring layer 1801 and the third wiring layer 1802.

The second wiring layer 1801 may include a second insulating layer 1821 and a second conductive structure 1831 in the second insulating layer 1821.

The second insulating layer 1821 may include a single layer or a plurality of layers. The second insulating layer 1821 may cover the top surface 1000a of the second substrate 1000. The second insulating layer 1821 may be formed of and/or contain a silicon-based insulating material such as silicon oxide, silicon nitride, and/or silicon oxynitride.

The second bonding pads 1851 and the second conductive structure 1831 may be provided in the second insulating layer 1821. The second bonding pads 1851 may be arranged adjacent to a top surface of the second insulating layer 1821 and may be in contact with the first bonding pads 850. The first bonding pads 850 and the second bonding pads 1851 may be integrally formed without a boundary surface but embodiments are not limited thereto. The first insulating layer 820 may also be directly bonded to the second insulating layer 1821. In this case, a chemical bond may be formed between the first insulating layer 820 and the second insulating layer 1821.

The second conductive structure 1831 may include a via portion and a wiring portion. The via portion may be provided in the second insulating layer 1821. The via portion may be electrically connected to the second bonding pads 1851. The wiring portion may be electrically connected to the via portion. In addition, the via portion penetrates through at least a portion of the second insulating layer 1821 and may be electrically connected to the wiring portion. The second conductive structure 1831 may receive the photoelectric signal output from the first sub-chip 10.

The second substrate 1000 may be a semiconductor substrate or a silicon on insulator (SOI) substrate. The semiconductor substrate may be formed of and/or include, for example, a silicon substrate, a germanium substrate, or a silicon-germanium substrate. The second substrate 1000 may further include a Group III element having a first conductivity type. Alternatively, the second substrate 1000 may further include a Group V element having a second conductivity type. This may vary depending on the design of the image sensor 1 to be manufactured.

The third wiring layer 1802 may be arranged on the bottom surface 1000b of the second substrate 1000. The third wiring layer 1802 may include a third insulating layer 1822 and a third conductive structure 1832 in the third insulating layer 1822.

The third insulating layer 1822 may include a single layer or a plurality of layers. The third insulating layer 1822 may cover the bottom surface 1000b of the second substrate 1000. The third insulating layer 1822 may be formed of and/or contain a silicon-based insulating material such as silicon oxide, silicon nitride, and/or silicon oxynitride.

The third bonding pads 1852 and the third conductive structure 1832 may be provided in the third insulating layer 1822. The third bonding pads 1852 may be arranged adjacent to a bottom surface of the third insulating layer 1822 and may be in contact with fourth bonding pads 2850. The third bonding pads 1852 and the fourth bonding pads 2850 may be integrally formed without a boundary surface but embodiments are not limited thereto. In this case, the third insulating layer 1822 may be directly bonded to a fourth insulating layer 2820. In this case, a chemical bond may be formed between the third insulating layer 1822 and the fourth insulating layer 2820.

The third conductive structure 1832 may include a via portion and a wiring portion. The via portion may be provided in the third insulating layer 1822. The via portion may be electrically connected to the third bonding pads 1852. The wiring portion may be electrically connected to the via portion. In addition, the via portion penetrates through at least a portion of the third insulating layer 1822 and may be electrically connected to the wiring portion.

A second floating diffusion region FD2 and second impurity regions 112 may be provided in the second substrate 1000. The second floating diffusion region FD2 and the second impurity regions 112 may be arranged adjacent to a bottom surface 1000b of the second substrate 1000. The second floating diffusion region FD2 may be electrically connected to the first floating diffusion region FD1 through a first through electrode TSV1.

The second floating diffusion region FD2 and the second impurity regions 112 may be regions doped with second conductivity type impurities (e.g., n-type impurities) or first conductivity type impurities (e.g., p-type impurities).

The second impurity regions 112 may be active regions. In this case, the active regions may refer to regions for operations of the transistor and may include source/drain regions of the transistor described with reference to FIGS. 2A and 2B. The transistor may include a source follower transistor Sx, a reset transistor Rx, or a selection transistor Ax described with reference to FIGS. 2A and 2B. However, the embodiments are not limited thereto, and the first impurity regions 111, not the second impurity regions 112, may include source/drain regions of the source follower transistor Sx, the reset transistor Rx, or the selection transistor Ax. This may vary depending on the design of the image sensor 1 to be designed.

A landing pad LP, a double conversion gain gate DCG, and first integrated circuits 1700 may be arranged on the bottom surface 1000b of the second substrate 1000. The landing pad LP may be a pad on which a conductive via lands during assembly. After assembly, the landing pad may provide an electrical connection between the conductive via and components electrically connected to the landing pad.

The landing pad LP and the double conversion gain gate DCG may be arranged in the third insulating layer 1822. At least a portion of the landing pad LP and at least a portion of the double conversion gain gate DCG may vertically overlap the second floating diffusion region FD2. The landing pad LP may be in contact with the second floating diffusion region FD2. The double conversion gain gate DCG may include a gate layer PG and a gate insulating layer GO between the second substrate 1000 and the gate layer PG. The gate layer PG may be spaced apart from the second floating diffusion region FD2 with the gate insulating layer GO therebetween. The landing pad LP and the gate layer PG may include the same material. For example, the landing pad LP and the gate layer PG may be formed of and/or include polycrystalline silicon. In this case, the polycrystalline silicon may include polycrystalline silicon doped with impurities. The gate insulating layer GO may be formed of and/or include an insulating material such as a silicon oxide layer.

A vertical level of a bottom surface of the landing pad LP may be higher than or equal to a vertical level of a bottom surface DCGb of the double conversion gain gate DCG. For example, the vertical level of the bottom surface DCGb of the double conversion gain gate DCG may be lower than or equal to the vertical level of the bottom surface of the landing pad LP.

The first integrated circuits 1700 may constitute a transistor together with the second impurity regions 112. The transistor may include a source follower transistor Sx, a reset transistor Rx, or a selection transistor Ax described with reference to FIGS. 2A and 2B.

The first integrated circuits 1700 may include a first integrated circuit gate 1701 and an integrated circuit insulating layer 1702 between the second substrate 1000 and the first integrated circuit gate 1701. The first integrated circuit gate 1701 may function as a gate electrode of the source follower transistor Sx, the reset transistor Rx, or the selection transistor Ax. That is, the first integrated circuit gate 1701 may correspond to the source follower gate SG, the reset gate RG, or the selection gate AG in FIGS. 2A and 2B. The first integrated circuit gate 1701 may be spaced apart from the second substrate 1000 with the integrated circuit insulating layer 1702 therebetween. The first integrated circuit gate 1701 may be electrically connected to any one of the third bonding pads 1852 through the third conductive structure 1832.

A first through electrode TSV1 penetrating through the second substrate 1000 may be provided. The first through electrode TSV1 may be electrically connected to the landing pad LP. The first through electrode TSV1 may extend in the third direction D3 to further penetrate through at least a portion of the second wiring layer 1801. The first through electrode TSV1 may be electrically connected to any one of the second bonding pads 1851 through a direct connection. Alternatively, the first through electrode TSV1 may be electrically connected to any one of the second bonding pads 1851 through the second conductive structure 1831. Accordingly, the landing pad LP may be electrically connected to the first floating diffusion region FD1 through the first through electrode TSV1 and the second bonding pad 1851. Accordingly, the second floating diffusion region FD2 may be electrically connected to any one of the first floating diffusion regions FD1 through the landing pad LP, the first through electrode TSV1, the second bonding pad 1851, the first bonding pad 850, and the first conductive structure 830.

The landing pad LP may be arranged in the third insulating layer 1822 to contact the first through electrode TSV1 and the second floating diffusion region FD2. As a result, the third conductive structure 1832 does not need to exist around the second floating diffusion region FD2 and the parasitic capacitance generated between the second floating diffusion region FD2 and the third conductive structure 1832 may be reduced to realize a high conversion gain. The high conversion gain may improve the image quality of the image sensor 1.

A first spacer SPC1 may be provided between the first through electrode TSV1 and the second substrate 1000. The first through electrode TSV1 may be spaced apart from the second substrate 1000 with the first spacer SPC1 therebetween. The first spacer SPC1 may be formed of and/or include a low dielectric material such as silicon oxide, silicon nitride, and silicon oxynitride.

A second through electrode TSV2 penetrating through the second substrate 1000 may be provided. The second through electrode TSV2 may extend in the third direction D3 and the opposite direction to further penetrate through at least a portion of the second wiring layer 1801 and at least a portion of the third wiring layer 1802. The second through electrode TSV2 may be electrically connected to any one of the second bonding pads 1851. The electrical connection may be formed through contact or a direct physical connection. Alternatively, the second through electrode TSV2 may be electrically connected to any one of the second bonding pads 1851 through the second conductive structure 1831. The second through electrode TSV2 may be electrically connected to another of the first floating diffusion regions FD1 through the second conductive structure 1831, the second bonding pad 1851, and the first conductive structure 830. The second through electrode TSV2 may be electrically connected to the third conductive structure 1832. The second through electrode TSV2 may be electrically connected to the first integrated circuit gate 1701 of the first integrated circuits 1700 through the third conductive structure 1832. A vertical level of a bottom surface TSV2b of the second through electrode TSV2 may be lower than a vertical level of a bottom surface TSV1b of the first through electrode TSV1. The vertical level of the bottom surface TSV2b of the second through electrode TSV2 may be lower than a vertical level of a bottom surface of the first integrated circuit gate 1701.

A second spacer SPC2 may be provided between the second through electrode TSV2 and the second substrate 1000. The second through electrode TSV2 may be spaced apart from the second substrate 1000 with the second spacer SPC2 therebetween. The second spacer SPC2 may include a low dielectric material such as silicon oxide, silicon nitride, and silicon oxynitride.

A third through electrode TSV3 penetrating through the second substrate 1000 may be provided. The third through electrode TSV3 may further extend in the third direction D3 and the opposite direction to further penetrate through at least a portion of the second wiring layer 1801 and at least a portion of the third wiring layer 1802. The third through electrode TSV3 may be electrically connected to the second conductive structure 1831 and the third conductive structure 1832. The third through electrode TSV3 may be electrically connected to any one of the second bonding pads 1851 through the second conductive structure 1831. The third through electrode TSV3 may be electrically connected to the transistor gate TG through the second conductive structure 1831, the second bonding pad 1851, and the first conductive structure 830. The third through electrode TSV3 may be electrically connected to any one of the third bonding pads 1852 through the third conductive structure 1832. A vertical level of a bottom surface TSV3b of the third through electrode TSV3 may be lower than or equal to a vertical level of a bottom surface TSV1b of the first through electrode TSV1.

A third spacer SPC3 may be provided between the third through electrode TSV3 and the second substrate 1000. The third through electrode TSV3 may be spaced apart from the second substrate 1000 with the third spacer SPC3 therebetween. The third spacer SPC3 may be formed of and/or include a low dielectric material such as silicon oxide, silicon nitride, and silicon oxynitride.

The first through electrode TSV1, the second through electrode TSV2, and the third through electrode TSV3 may be formed of and/or include a metal. For example, the first through electrode TSV1, the second through electrode TSV2, and the third through electrode TSV3 may include metals such as aluminum, copper, tungsten, titanium, tantalum, or alloys thereof.

The third sub-chip 30 may be arranged below the second sub-chip 20. The third sub-chip 30 may include a fourth wiring layer 2800 and a third substrate 2000. The third wiring layer 1802 may be placed between the fourth wiring layer 2800 and the second substrate 1000. The second integrated circuits 2700 may be arranged on the top surface of the third substrate 2000 or in the third substrate 2000. The second integrated circuits 2700 may include logic circuits, memory circuits, or a combination thereof. The second integrated circuits 2700 may include, for example, transistors. The fourth wiring layer 2800 may include a fourth insulating layer 2820 and a fourth conductive structure 2830. The fourth insulating layer 2820 may include a single layer or a plurality of layers. The fourth conductive structures 2830 may be provided in the fourth insulating layer 2820. The fourth conductive structures 2830 may be electrically connected to the second integrated circuits 2700. The fourth conductive structures 2830 may further include a via pattern, and the via pattern may be electrically connected to the fourth conductive structures 2830 in the fourth insulating layer 2820.

Referring to FIG. 5, the first through electrode TSV1 may be in contact with the landing pad LP. Specifically, the bottom surface TSV1b of the first through electrode TSV1 may be in contact with at least a portion of the top surface LPa of the landing pad LP. A vertical level of a bottom surface TSV1b of the first through electrode TSV1 may be equal to a vertical level of a bottom surface 1000b of the second substrate 1000. That is, the bottom surface TSV1b of the first through electrode TSV1 may be coplanar with the bottom surface 1000b of the second substrate 1000.

A bottom surface of the second floating diffusion region FD2 may include a first bottom surface portion FD2b1 and a second bottom surface portion FD2b2. The first bottom surface portion FD2b1 may be a portion of the bottom surface of the second floating diffusion region FD2 that vertically overlaps at least a portion of the landing pad LP. The first bottom surface portion FD2b1 may be in contact with at least a portion of the top surface LPa of the landing pad LP. The second lower surface portion FD2b2 may be a portion of the bottom surface of the second floating diffusion region FD2 that vertically overlaps at least a portion of the double conversion gain gate DCG. The second bottom surface portion FD2b2 may be in contact with at least a portion of the top surface GOa of the double conversion gain gate DCG. The second floating diffusion region FD2 may be in contact with the third insulating layer 1822.

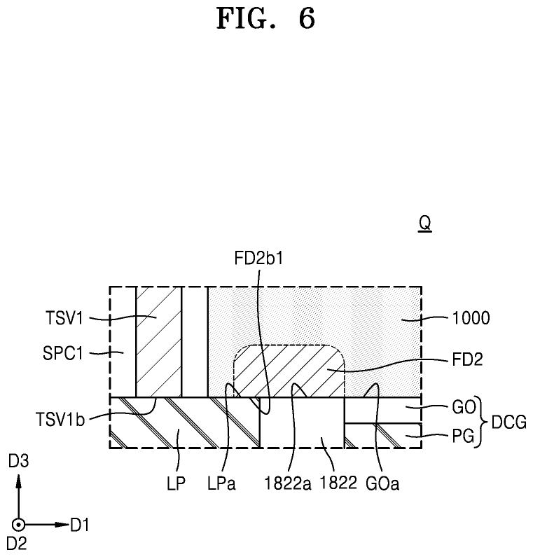

FIG. 6 is an enlarged cross-sectional view corresponding to the Q region of FIG. 4 illustrating an alternative an image sensor according to an embodiment. Hereinafter, the description of like elements as indicated by like reference characters may be limited or omitted with the understanding that elements were previously described with reference to FIG. 5. Elements that were not described previously or that have differences from those described may be described in greater detail with reference to FIG. 6.

Referring to FIG. 6, the second floating diffusion region FD2 may not vertically overlap the double conversion gain gate DCG. That is, the second floating diffusion region FD2 includes the first bottom surface portion FD2b1 that vertically overlaps at least a portion of the top surface LPa of the landing pad LP, and may not include a second bottom surface portion such as the second bottom surface portion FD2b2 as shown in FIG. 5.

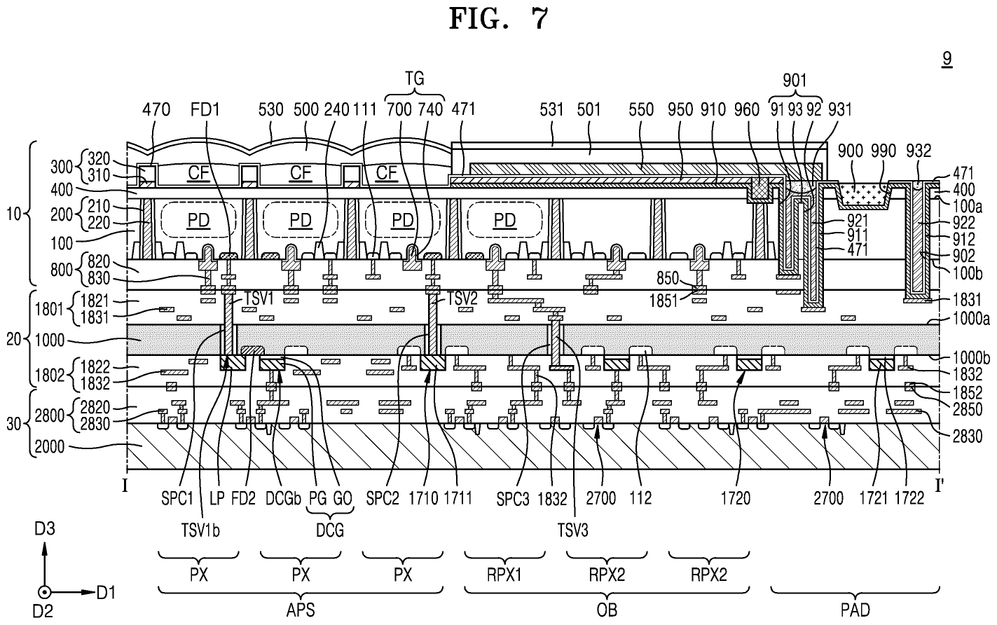

FIG. 7 is a cross-sectional view for describing an image sensor according to another embodiment, which corresponds to a cross-section taken along line I-I′ of FIG. 3. Hereinafter, the description of like elements as indicated by like reference characters may be limited or omitted with the understanding that elements were previously described with reference to FIGS. 3 to 5. Elements that were not described previously or that have differences from those described may be described in greater detail with reference to FIG. 7.

In the embodiment of FIG. 7, the second through electrode TSV2 of the image sensor 9 may not penetrate the third wiring layer 1802. The bottom surface of the second through electrode TSV2 may be in contact with the second integrated circuit gate 1711 of the third integrated circuit 1710 arranged on the bottom surface 1000b of the second substrate 1000. The third integrated circuit 1710 may constitute a transistor together with the second impurity regions 112 like the first integrated circuit 1700. The third integrated circuit 1710 may not include a component corresponding to the gate insulating layer GO of FIG. 4.

A vertical level of the bottom surface of the second through electrode TSV2 may be the same as a vertical level of the bottom surface TSV1b of the first through electrode TSV1. For example, a bottom surface of the first through electrode TSV1 and a bottom surface of the second through electrode TSV2 may be coplanar.

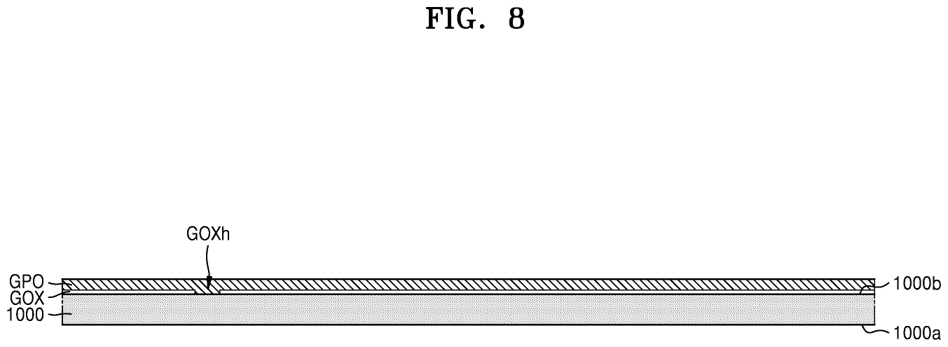

FIGS. 8 to 12 are cross-sectional views sequentially illustrating a method of manufacturing an image sensor according to an embodiment.

Referring to FIG. 8, a preliminary gate insulating layer GOX and a preliminary gate layer GPO may be sequentially formed on a second substrate 1000. The second substrate 1000 shown in FIG. 8 is inverted relative to the previous figures such that a top surface of the second substrate 1000 corresponds to the bottom surface 1000b of the previous figures and a bottom surface of the second substrate 1000 corresponds to the top surface 1000a of the previous figures. Before forming the preliminary gate layer GPO, a first opening GOXh may be formed in the preliminary gate insulating layer GOX. A portion of the top surface (corresponding to bottom surface 1000b) of the second substrate 1000 may be exposed through the first opening GOXh. The preliminary gate insulating layer GOX may be formed of and/or include an insulating material such as silicon oxide. The preliminary gate layer GPO may be formed of and/or include polycrystalline silicon. The preliminary gate insulating layer GOX and the preliminary gate layer GPO may be formed by physical vapor deposition (PVD), chemical vapor deposition (CVD), atomic layer deposition (ALD), and the like.

Ions may be implanted into the preliminary gate layer GPO. The ions may include impurities of the first conductivity type or the second conductivity type. Accordingly, the preliminary gate layer GPO may include polycrystalline silicon doped with impurities.

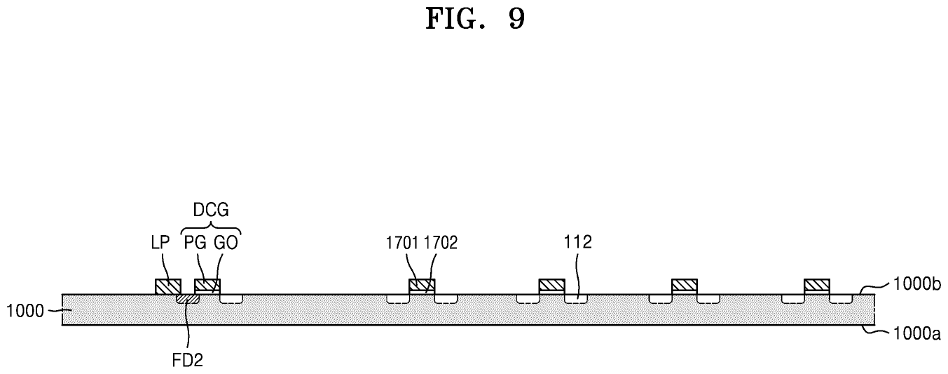

Referring to FIG. 9, the preliminary gate insulation layer GOX and the preliminary gate layer GPO may be patterned to form a landing pad LP, a double conversion gain gate DCG, a first integrated circuit gate 1701, and an integrated circuit insulation layer 1702. The process of forming of the landing pad LP, the double conversion gain gate DCG, the first integrated circuit gate 1701, and the integrated circuit insulating layer 1702 may include performing a photolithography process and an etch process on the preliminary gate insulating layer GOX.

Thereafter, ions may be injected to form second floating diffusion regions FD2 and second impurity regions 112.

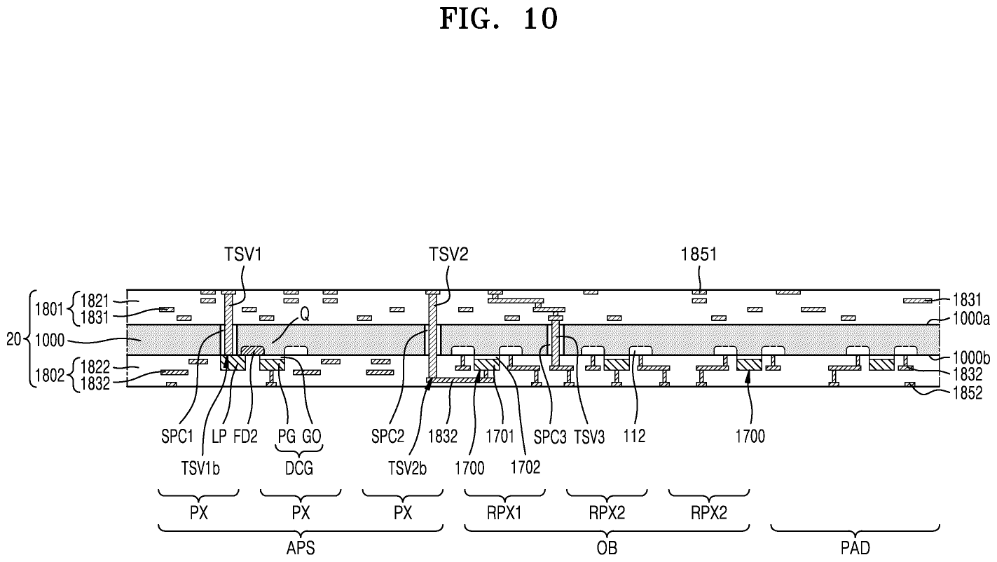

Referring to FIG. 10, the structure of FIG. 9 is inverted such that the bottom surface of FIG. 9 corresponds to the top surface 1000a of FIG. 10 and the top surface of FIG. 9 corresponds to the bottom surface 1000b of FIG. 10. A third wiring layer 1802 may be formed on the bottom surface 1000b of the second substrate 1000. The third wiring layer 1802 may be formed continuously. The third wiring layer 1802 may include a third insulating layer 1822 and a third conductive structure 1832. First integrated circuits 1700 including the first integrated circuit gate 1701, the integrated circuit insulating layer 1702, and the third conductive structure 1832 may be embedded in the third wiring layer 1802 as it is formed.

In FIG. 10, a second wiring layer 1801 may be formed on the top surface 1000a of the second substrate 1000. The second wiring layer 1801 may include a second insulating layer 1821 and a second conductive structure 1831. Subsequently, a first through electrode TSV1, a second through electrode TSV2, and a third through electrode TSV3 may be formed. The first through electrode TSV1 and the second through electrode TSV2 may penetrate through the second insulating layer 1821 and the second substrate 1000. The second through electrode TSV2 may further penetrate through at least a portion of the third insulating layer 1822. The third through electrode TSV3 may further penetrate through at least a portion of the second insulating layer 1821 and at least a portion of the third insulating layer 1822. Subsequently, second bonding pads 1851 may be formed adjacent to the top surface of the second wiring layer 1801. Accordingly, the second sub-chip 20 may be formed.

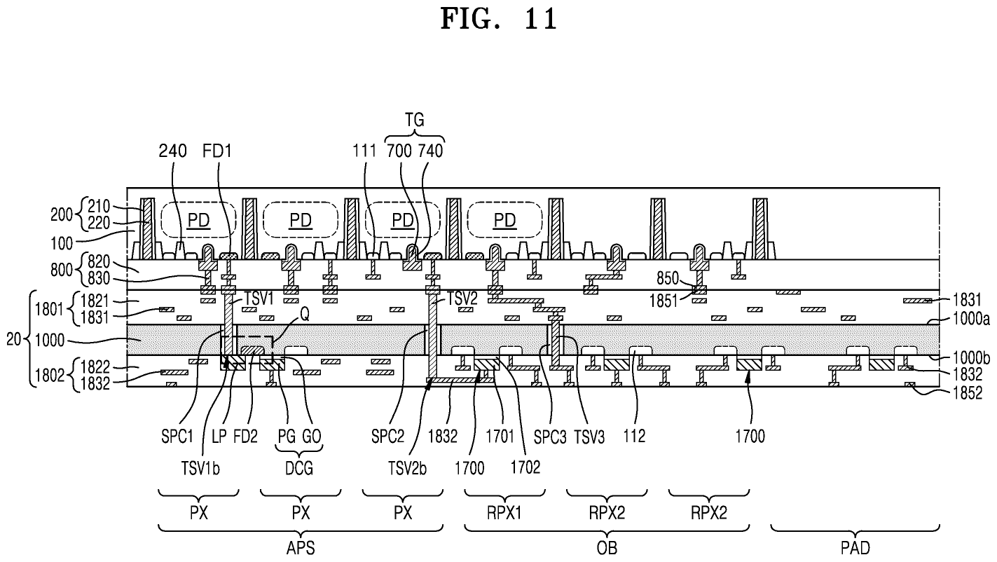

Referring to FIG. 11, a first wiring layer 800 and a first substrate 100 may be formed on the second wiring layer 1801. The first wiring layer 800 and the first substrate 100 may be formed separately from the second substrate 1000 and then bonded onto the second substrate 1000. Specifically, a photoelectric conversion region PD, an isolation pattern 200, a device isolation pattern 240, a first floating diffusion region FD1, first impurity regions 111, and a transfer gate TG may be formed on the first substrate 100. Thereafter, the first wiring layer 800 may be formed on the first substrate 100. The first bonding pads 850 adjacent to the upper surface of the first wiring layer 800 may be formed. Thereafter, the first substrate 100 and the first wiring layer 800 may be inverted to be positioned on the second wiring layer 1801, and the first bonding pads 850 and the second bonding pads 1851 may be bonded thereto, respectively.

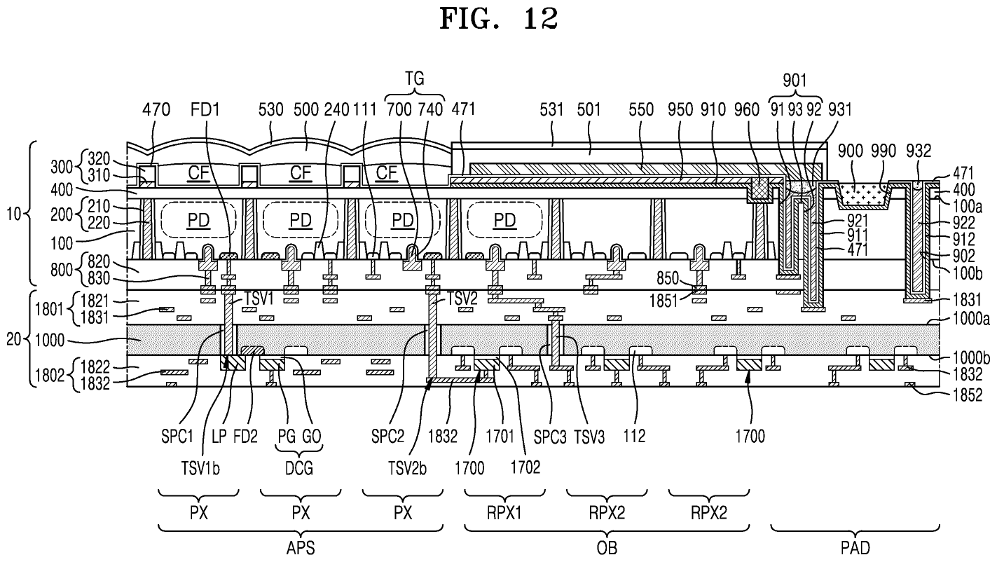

Referring to FIG. 12, a planarization process may be performed on the first substrate 100 to expose the isolation pattern 200. An upper insulating layer 400 may be formed on the first substrate 100 and the isolation pattern 200. Thereafter, a contact trench (not shown), a first through hole 901, a second through hole 902, and a pad trench 990 may be formed.

A conductive pattern layer 910 including a first conductive pattern 911 and a second conductive pattern 912 may be formed. The conductive pattern layer 910 may cover a portion of the upper insulating layer 400 and inner walls of the contact trench. The first conductive pattern 911 may cover inner walls and bottom surfaces of the first through hole 901. The second conductive pattern 912 may cover inner walls and bottom surfaces of the second through hole 902.

A contact plug 960 may be formed. The forming of the contact plug 960 may include depositing a metal layer (not shown) on the whole surface of the conductive pattern layer 910 and performing a dry etching process on the metal layer.

A light blocking layer 950 may be formed. The light blocking layer 950 may be formed on the first surface 100a of the optical black region OB of the first substrate 100.

A fence pattern 300 may be formed. The forming of the fence pattern 300 may include depositing a first fence pattern layer (not shown) and a second fence pattern layer (not shown), and performing a dry etching process on the first fence pattern layer and the second fence pattern layer to form a first fence pattern 310 and a second fence pattern 320.

A protective layer 470 and a protective insulating layer 471 may be formed. The protective layer 470 may cover a top surface and side surfaces of the fence pattern 300 and a portion of a top surface of the upper insulating layer 400. The protective insulating layer 471 may cover a top surface of the light blocking layer 950. The protective insulating layer 471 may cover surfaces of a first conductive pattern 911 and a second conductive pattern 912 inside a first through hole 901 and a second through hole 902.

A first buried pattern 921 filling the first through hole 901 may be formed. A second buried pattern 922 filling the second through hole 902 may be formed.

A first capping pattern 931 may be formed on the first buried pattern 921. A second capping pattern 932 may be formed on the second buried pattern 922.

Color filters CF and a microlens layer 500 may be formed on a pixel array region APS. A lens coating layer 530 may be formed on the microlens layer 500.

A filtering layer 550, an organic layer 501, and a coating layer 531 may be formed on the optical black region OB.

A pad terminal 900 may be formed on the pad region PAD. Accordingly, the first sub-chip 10 may be formed.

Referring back to FIG. 4, a third sub-chip 30 manufactured separately from the first sub-chip 10 and the second sub-chip 20 may be arranged below the second sub-chip 20. The third sub-chip 30 may include the components described with reference to FIG. 4. The fourth bonding pads 2850 of the third sub-chip 30 and the third bonding pads 1852 of the second sub-chip 20 may be bonded, respectively. Accordingly, the image sensor 1 may be manufactured.

The description of FIGS. 8 to 12 discloses a manufacturing method including bonding the first substrate 100 and the first wiring layer 800 on the second sub-chip 20 first, and then bonding the third sub-chip 30 to the second sub-chip 20. However, the manufacturing method according to the inventive concept is not limited thereto. In an embodiment, the third sub-chip 30 may be formed first, and then the second sub-chip 20 formed separately from the third sub-chip 30 may be bonded onto the third sub-chip 30. Subsequently, the first substrate 100 and the first wiring layer 800 may be bonded on the second sub-chip 20, and remaining components such as color filters CF and microlens layer 500 may be formed on the first substrate 100. This may vary depending on the design of the image sensor 1 to be manufactured.

While the inventive concept has been particularly shown and described with reference to embodiments thereof, it will be understood that various changes in form and details may be made therein without departing from the spirit and scope of the following claims.

What is claimed is:

1. An image sensor comprising:
a first substrate including a first surface to which light is incident and a second surface opposite the first surface;
a second substrate facing the second surface of the first substrate;
a wiring layer between the first substrate and the second substrate and including an insulating layer and a conductive structure in the insulating layer;
a first floating diffusion region provided in the first substrate;
a first through electrode penetrating through the second substrate and electrically connected to the first floating diffusion region through the conductive structure;
a second floating diffusion region provided in the second substrate; and
a landing pad arranged at a bottom surface of the second substrate and electrically connected to the second floating diffusion region,
wherein a bottom surface of the first through electrode is in contact with the landing pad.

2. The image sensor of claim 1, wherein the bottom surface of the first through electrode is coplanar with the bottom surface of the second substrate.

3. The image sensor of claim 1, further comprising
a double conversion gain gate arranged at the bottom surface of the second substrate and spaced apart from the landing pad with the second floating diffusion region disposed therebetween,
wherein the double conversion gain gate comprises a gate layer and a gate insulating layer between the second substrate and the gate layer, and the landing pad and the gate layer comprise the same material.

4. The image sensor of claim 3, wherein
the landing pad and the gate layer are formed of polycrystalline silicon doped with impurities.

5. The image sensor of claim 3, wherein
the landing pad and the second floating diffusion region are in contact with each other, and
the gate layer and the second floating diffusion region are spaced apart from each other with the gate insulating layer therebetween.

6. The image sensor of claim 1, further comprising:
a third floating diffusion region provided in the first substrate;
a second through electrode penetrating through the second substrate and electrically connected to the third floating diffusion region; and
an integrated circuit arranged on the bottom surface of the second substrate and including a gate,
wherein the second through electrode is electrically connected to the gate of the integrated circuit.

7. The image sensor of claim 6, wherein
a vertical level of the bottom surface of the second through electrode is lower than a vertical level of the bottom surface of the first through electrode.

8. The image sensor of claim 6, wherein
the bottom surface of the second through electrode is coplanar with the bottom surface of the first through electrode.

9. The image sensor of claim 1, wherein
at least a portion of the second floating diffusion region vertically overlaps with the landing pad.

10. The image sensor of claim 9, further comprising
a double conversion gain gate arranged on the bottom surface of the second substrate and spaced apart from the landing pad with the second floating diffusion region therebetween,
wherein at least a portion of the second floating diffusion region vertically overlaps with the double conversion gain gate.

11. The image sensor of claim 1, further comprising:
a gate pattern arranged on the second surface of the first substrate; and
a second through electrode penetrating through the second substrate,
wherein the gate pattern and the second through electrode are electrically connected through the conductive structure.

12. An image sensor comprising:
a first sub-chip having an upper surface and a lower surface; and
a second sub-chip below the first sub-chip,
wherein
the first sub-chip comprises:
a first substrate;
a first floating diffusion region arranged in the first substrate; and
a first wiring layer arranged below the first substrate; and
the second sub-chip comprises:
a second substrate;
a second floating diffusion region arranged in the second substrate;
a second wiring layer on a bottom surface of the second substrate;
a first through electrode penetrating through the second substrate;
a landing pad arranged in the second wiring layer and electrically connected to the first through electrode and the second floating diffusion region; and
a double conversion gain gate arranged on the bottom surface of the second substrate and spaced apart from the landing pad with the second floating diffusion region therebetween,
wherein a vertical level of a bottom surface of the first through electrode is higher than a vertical level of a bottom surface of the double conversion gain gate.

13. The image sensor of claim 12, wherein
the vertical level of the bottom surface of the double conversion gain gate is lower than or equal to the vertical level of a bottom surface of the landing pad.

14. The image sensor of claim 12, wherein
the double conversion gain gate comprises a gate layer and a gate insulating layer between the second substrate and the gate layer, and
the gate layer and the landing pad comprise the same material.

15. The image sensor of claim 12, further comprising:
a third floating diffusion region provided in the first substrate;
a second through electrode penetrating through the second substrate and electrically connected to the third floating diffusion region; and
an integrated circuit arranged on the bottom surface of the second substrate and including a gate,
wherein the bottom surface of the second through electrode is in contact with a top surface of the gate of the integrated circuit.

16. The image sensor of claim 15, wherein
the landing pad and the gate of the integrated circuit are formed of the same material.

17. The image sensor of claim 15, wherein
the second wiring layer comprises an insulating layer and a conductive structure in the insulating layer, and
the first through electrode and the second through electrode are spaced apart from the conductive structure.

18. The image sensor of claim 12, wherein
the second wiring layer comprises an insulating layer and a conductive structure in the insulating layer, and
the vertical level of the bottom surface of the first through electrode is the same as the vertical level of a top surface of the second wiring layer.

19. An image sensor comprising:
a first sub-chip;
a second sub-chip below the first sub-chip; and
a third sub-chip below the second sub-chip,
wherein
the first sub-chip comprises:
a first substrate including an upper surface to which light is incident and a lower surface opposing the upper surface;
color filters arranged on the upper surface of the first substrate;
a microlens layer arranged on the color filters;
a first floating diffusion region within the first substrate; and
a gate pattern arranged on the lower surface of the first substrate,
the second sub-chip comprises:
a second substrate;
a second floating diffusion region arranged in the second substrate;
a first wiring layer on a bottom surface of the second substrate;
a through electrode penetrating through the second substrate and extending in a direction perpendicular to a top surface of the second substrate and electrically connected to the first floating diffusion region; and
a landing pad arranged in the first wiring layer and electrically connected to the through electrode and the second floating diffusion region, and
the third sub-chip comprises:
a third substrate;
a second wiring layer arranged on the third substrate and in contact with the first wiring layer; and
integrated circuits arranged at a top surface of the third substrate,
wherein the first wiring layer comprises an insulating layer and a conductive structure in the insulating layer, and the through electrode is spaced apart from the insulating layer.

20. The image sensor of claim 19, wherein
at least a portion of the landing pad vertically overlaps the second floating diffusion region.
